(19) United States
(12) Patent Application Publication
(10) Pub. No.: US 2010/0273098 A1
(43) Pub. Date: Oct. 28, 2010

(54) MASK BLANK, PRODUCTION METHOD OF MASK BLANK AND PRODUCTION METHOD OF MASK

(75) Inventors: Takumi Ogawa, Chichibu-shi (JP); Akira Kurabayashi, Chichibu-shi (JP); Go Hiramoto, Chichibu-shi (JP)

Correspondence Address: J. Rodman Steele;Novak Druce & Quigg LLP, 525 Okeechobee Blvd, Suite 1500, West Palm Beach, FL, 33401, US

(73) Assignee: ULVAC COATING CORPORAATION, Saitama (JP)

(21) Appl. No.: 12/810,157

(22) PCT Filed: Dec. 22, 2008
(86) PCT No.: PCT/JP2008/073356

§ 371 Date: Jun. 23, 2010

(30) Foreign Application Priority Data
Dec. 27, 2007 (JP) 2007-337614

(51) Int. Cl. G03F 1/00

(52) U.S. Cl. 430/5

(57) ABSTRACT

A mask blank that can be formed without causing a shape defect in a transfer pattern having a high resolution. A mask blank (10) includes a transparent substrate (11), an etched layer (14) located above the transparent substrate (11), a suppression layer (20) located above the etched layer (11) and formed using a first chemical amplification resist, and a mask layer (15) located above the suppression layer (20) and formed using a second chemical amplification resist. The mask layer (15) functions to generate acid with the second chemical amplification resist when receiving exposure light and change solubility of the mask layer (15) with respect to a development liquid. The suppression layer (20) functions to generate acid with the first chemical amplification resist when receiving the exposure light through the mask layer (15) and obtain insolubility of the mask layer (15) with respect to the development liquid.

### TECHNICAL FIELD

The present invention relates to a mask blank, a method for manufacturing a mask blank, and a method for manufacturing a mask.

### BACKGROUND ART

A technique for manufacturing a semiconductor device uses a photomask that includes a light-blocking transfer pattern on a transparent substrate to miniaturize various types of patterns. The transfer pattern of the photomask is obtained by forming a resist mask on a light-blocking film, which is applied to the transparent substrate, and patterning the light-blocking film with the resist mask. A chemical amplification resist has been used in the prior art as the material used as the resist mask to improve the resolution (patterning property) and throughput of the light-blocking film.

The chemical amplification resist, which is a composition including a base resin and an acid generation agent, generates acid serving as a catalytic substance when the acid generation agent receives exposure light. The acid generated by the exposure is then heated thereby reacting with a functional group or functional substance, which influences the solubility of the base resin, so that the resist material obtains a resist function. In other words, the acid generated by the exposure advances the cross-linking reaction of a negative type resist, and advances the decomposition reaction of a positive type resist. This allows for the chemical amplification resist to pattern the resist with a small exposure amount.

When using a chemical amplification resist as the resist material, a base may exist on the surface of the light-blocking film and acid generated by the exposure may be diffused to the light-blocking film at the interface of the resist film and the light-blocking film. This may impair the catalytic action of the acid generated by the exposure. As a result, the resolution of the resist film decreases near the surface of the light-blocking film, and a significant shape defect may occur in the resist mask. For example, a shape defect in which the resist mask spreads near the surface of the light-blocking film occurs in the positive type resist, and a shape defect in which the resist mask becomes small near the surface of the light-blocking film occurs in the negative type resist. Accordingly, in the photomask manufacturing technology, various proposals have been made to solve such shape defects.

In patent document 1, a high density inorganic film, which is formed from a silicide material, is arranged as a suppression layer between the light-blocking film and the chemical amplification resist. The suppression layer suppresses the diffusion of acid to the light-blocking film. This, in turn, suppresses the shape defect of the resist mask. Further, in patent document 2, a suppression layer, which is formed from an organic material having a higher etching rate than the resist mask, is arranged between the light-blocking film and the chemical amplification resist. This obtains a selection ratio between the suppression layer and the resist mask. Thus, deformation of the resist mask is suppressed in the etching of the suppression layer, and a light-blocking layer having a higher resolution may be patterned.

However, when using an inorganic film as the suppression layer, the shape of the resist mask, the surface roughness of the light-blocking film easily changes the density of the inorganic film. This results in large variations in the shape of the resist mask and, consequently, the transfer pattern. Further, to form the transfer pattern, a process for patterning the suppression layer and a process for removing the suppression layer are additionally required. This increases the number of steps for producing the photomask increases and significantly lowers the productivity of the photomask.

When using organic material for the suppression layer, the density of the organic film is lower than an inorganic film. Thus, the diffusion of acid to the light-blocking film cannot be sufficiently prevented. Further, the infiltration of base components from the light-blocking film is difficult to prevent. Thus, a suppression layer formed from an organic material requires a thickness of, for example, 30 nm or greater to prevent acid diffusion of and base infiltration. Accordingly, it is more difficult to decrease the thickness than with an inorganic film, and a shape defect of the resist mask would occur when decreasing the thickness of the suppression layer. On the other hand, when increasing the thickness of the suppression layer, the resist mask is greatly etched and the resolution of the light-blocking film is significantly decreased when etching the suppression layer with the resist mask.

Patent Document 1: Japanese Laid-Open Patent Publication No. 2003-107675

Patent Document 2: Japanese Laid-Open Patent Publication No. 2007-171520

### DISCLOSURE OF THE INVENTION

The present invention provides a mask blank, a method for manufacturing a mask blank, and a method for manufacturing a mask that allows for the formation of a transfer pattern having a high resolution without the occurrence of a shape defect in the transfer pattern.

A first aspect of the present invention is a mask blank. The mask blank includes a transparent substrate, an etched layer located above the transparent substrate, a suppression layer located above the etched layer and formed using a first chemical amplification resist, and a mask layer located above the suppression layer and formed using a second chemical amplification resist. The mask layer functions to generate acid with the second chemical amplification resist when receiving exposure light and change solubility of the mask layer with respect to a development liquid. The suppression layer functions to generate acid with the first chemical amplification resist when receiving the exposure light through the mask layer and obtain insolubility of the mask layer with respect to the development liquid.

A second aspect of the present invention is a method for manufacturing a mask blank. The method includes the steps of forming an etched layer on a transparent substrate, forming a suppression layer on the etched layer using a first chemical amplification resist, and forming a mask layer on the suppression layer using a second chemical amplification resist. The step of forming the mask layer includes applying the second chemical amplification resist to the suppression layer and removing solvent from the second chemical amplification resist. The step of forming the suppression layer includes applying the first chemical amplification resist to the etched layer and heating the first chemical amplification resist to remove solvent from the first chemical amplification resist. The suppression layer functions to obtain insolubility of the mask layer with respect to a development liquid due to the first chemical amplification resist when receiving exposure light, which exposes the mask layer.

A third aspect of the present invention is a method for manufacturing a mask. The method includes the steps of manufacturing the mask blank using the method for manufacturing a mask blank according to the second aspect, forming a resist mask by irradiating the mask layer of the mask blank with the exposure light, and forming a transfer pattern by etching the suppression layer and the etched layer of the mask blank using the resist mask.

### BRIEF DESCRIPTION OF THE DRAWINGS

FIG. 1 is a cross-sectional view showing a mask blank.

FIG. 2 is a cross-sectional view showing the mask blank.

FIG. 3 is a flowchart showing a method for manufacturing the mask blank.

FIG. 4 is a flowchart showing a method for manufacturing a mask.

FIG. 5 is a diagram showing one step in the mask manufacturing method.

FIG. 6 is a diagram showing one step in the mask manufacturing method.

FIGS. 7A and 7B are respectively SME images showing transfer patterns of an example and a comparative example.

### DESCRIPTION OF REFERENCE CHARACTERS

10: mask blank, 11: transparent substrate, 12: light-blocking film, 13: anti-reflection film, 14: underlayer, 15: mask layer, 15P: resist mask, 20: suppression layer

### BEST MODE FOR CARRYING OUT THE INVENTION

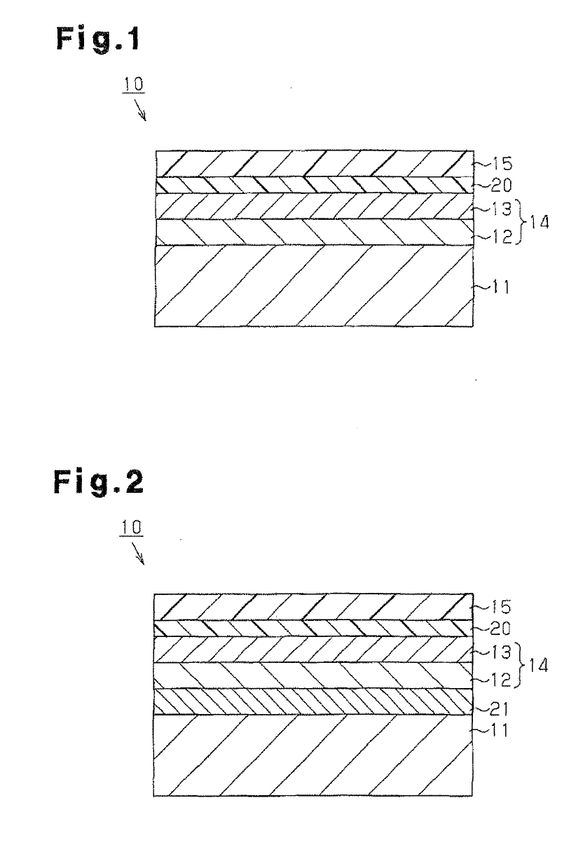

A mask blank 10 according to one embodiment of the present invention will now be discussed with reference to the drawings. FIGS. 1 and 2 are cross-sectional views, each showing the mask blank 10.

In FIG. 1, on a transparent substrate 11, the mask blank 10 includes a light-blocking film 12, which blocks exposure light, and an anti-reflection film 13, which prevents the reflection of exposure light. In the present embodiment, the light-blocking film 12 and the anti-reflection film 13 form an underlayer 14 serving as an etched layer.

A synthetic silica substrate, for example, may be used as the transparent substrate 11. Chromium, for example, may be used as the light-blocking film 12. An oxide, nitride, carbide, or oxynitride of one selected from a group consisting of chromium, molybdenum, tungsten, tantalum, titanium, vanadium, and zirconium may be used as the anti-reflection film 13.

A mask layer 15, which is formed using a chemical amplification photoresist, is arranged as the uppermost layer of the mask blank 10. A suppression layer 20, which prevents the resolution of the mask layer 15 from decreasing and is formed using a chemical amplification photoresist, is arranged between the mask layer 15 and the underlayer 14.

In the present embodiment, the chemical amplification resist for forming the mask layer 15 is referred to as a mask resist, and the chemical amplification resist for forming the suppression layer 20 is referred to as a suppression resist.

A chemical amplification resist is a composition including a base resin, which changes the solubility with respect to an alkaline solution serving as a development liquid, and an acid generation agent, which generates acid with exposure light. For example, an onium salt acid generation agent, such as a sulfonium salt acid generation agent and an iodonium salt acid generation agent, an oxime sulfonate acid generation agent, or an imide-sulfonate acid generation agent may be used as the acid generation agent. For example, a para-hydroxy styrene resin and its derivative may be used as the base resin. For example, for a positive type, a structure in which part of a hydroxyl group of a para-hydroxy styrene resin is substituted by an acetal protective group having an alkaline insoluble structure may be used. For a negative type, a mixture of a para-hydroxy styrene resin soluble to alkaline and a cross-linking agent may be used. For example, an electron beam accelerated to 50 kV or a SUV laser light having a wavelength of 257 nm may be used as a light source for exposure light.

The chemical amplification resist is applied to a subject in a state including an organic solvent and solidified by removing the organic solvent. The chemical amplification resist absorbs exposure light from when solidified so that the acid generation agent generates acid. This changes the alkaline solubility of the base resin through reaction of the substituent of the base resin and acid, reaction of the cross-linking agent and the acid, and the like. Ketones, alcohols, ethers, ester, and the like may be used as the organic solvent.

The mask layer 15 is a layer in which the organic solvent included in the mask resist is removed and solidified through heating. The mask layer 15 is formed by heating the mask resist applied to the suppression layer 20. The mask layer 15 has a thickness of 500 nm or less, preferably 400 nm or less, and more preferably 300 nm or less in order to form an ultra-fine transfer pattern. A positive type that includes an alkaline insoluble base resin and absorbs exposure light to obtain alkaline solubility may be used as the mask resist. Alternatively, a negative type that includes an alkaline soluble base resin and absorbs exposure light to obtain alkaline insolubility may be used as the mask resist.

The mask layer 15 generates acid with the acid generation agent when receiving exposure light in a resist mask formation process (mask manufacturing process). The mask layer 15 causes reaction between the acid generated by the exposure and a functional group or functional substance that influences the solubility of the base resin so that the mask layer 15 obtains alkaline insolubility or alkaline solubility.

The suppression layer 20 is a layer formed by a cross-linked base resin and is a layer including an acid generation agent. The suppression layer 20 is formed by excessively heating a suppression resist applied to the underlayer 14. More specifically, the suppression layer 20 is formed by removing the organic solvent from the suppression resist through heating and by cross-linking the base resin included in the suppression resist through further heating. The suppression layer 20 has a thickness that is sufficiently less than the mask layer 15 and is, for example, 1 nm to 200 nm, preferably 1 nm to 50 nm, and more preferably 1 nm to 30 nm. A negative type that includes alkaline soluble base resin and obtains alkaline insolubility through baking (heating) and through further irradiation of exposure light may be used as the suppression resist.

The suppression layer 20 generates acid with the acid generation agent when receiving the exposure light in a transfer pattern formation process (mask manufacturing process). The suppression layer 20 mutually diffuses the acid generated by the acid generation agent between the mask layer 15 and the suppression layer 20. In the suppression layer 20, the base resin is cross-linked. Thus, the density is high. As a result, the suppression layer 20 suppresses acid diffusion from the mask layer 15 and infiltration of the base from the underlayer 14 thereby ensuring prevention of acid reduction in the mask layer 15.

As shown in FIG. 2, the mask blank 10 may be formed with a phase shift halftone film 21, which shifts the phase of exposure light, between the transparent substrate 11 and the underlayer 14. Various known halftone films of, for example, chromium (CrO, CrF, etc.), molybdenum (MoSiON, MoSiN, MoSiO, etc.), tungsten (WSiON, WSiN, WSiO, etc.), and silicon (SiN, etc.) may be used as the phase shift halftone film 21.

The mask blank 10 includes an absorption body film of a tantalum material or chromium material to form a transfer pattern on a multi-layer reflection film or a buffer layer, which is arranged on the multi-layer reflection film. The absorption body film may be used as the underlayer 14. The mask blank 10 also includes a transfer pattern forming thin film of a chromium material or the like to form the transfer pattern. The transfer pattern forming thin film may be used as the underlayer 14.

Accordingly, the mask blank 10 of the present embodiment includes a photomask blank, a phase shift mask blank, a reflection mask blank, and an imprint transfer substrate.

A method for manufacturing the mask blank 10 will now be discussed. In the mask blank manufacturing method, a formation step of the suppression layer 20, which is a feature of the present invention, is the same regardless of the type of mask blank, and a formation step of the underlayer 14 differs in accordance with the type of mask blank. Thus, a method for manufacturing the mask blank 10 shown in FIG. 1 will now be discussed.

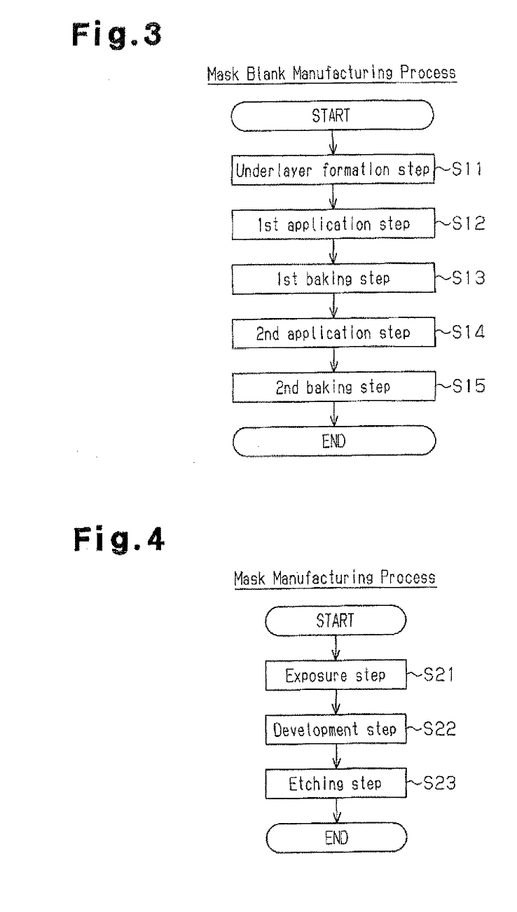

FIG. 3 is a flowchart showing the mask blank manufacturing method. As shown in FIG. 3, the manufacturing method of the mask blank 10 first performs sputtering or the like to form the underlayer 14 on the transparent substrate 11 (underlayer formation step: step S11). After the underlayer 14 is formed, spin coating or the like is performed to form an application film of a suppression resist on the surface of the underlayer 14 (first application step: step S12).

After the application film of the suppression resist is formed on the surface of the underlayer 14, a baking device is used to perform an excessive baking process on the suppression resist application film (first baking step: step S13). In the first baking step, organic solvent included in the suppression resist is removed through heating, and base resin included in the suppression resist is cross-linked through further heating. This forms the suppression layer 20 that is insoluble on the surface of the underlayer 14 in the manufacturing stage of the mask blank 10. The excessive baking includes a heating process performed under a higher temperature and/or longer time than the baking in a subsequent second baking step. In the first baking step, by excessively heating the suppression resist at a higher temperature and/or longer time than normal baking (i.e., second baking step), variations in the characteristics of the suppression layer 20 are suppressed through the subsequent heating of the mask resist. Accordingly, the insolubility of the suppression layer 20 is maintained in a preferred manner during the manufacturing stage of the mask blank 10.

When the suppression layer 20 is formed, spin coating or the like is performed to form an application film of a mask resist on the surface of the suppression layer 20 (second application step: step S14). After the application film of the mask resist is formed on the surface of the suppression layer 20, the baking device is used to perform a baking process on the application film of the mask resist (second baking step: step S15). In the second baking step, the organic solvent included in the mask resist is removed through heating. This forms the mask layer 15 on the surface of the suppression layer 20 and forms the mask blank 10.

The manufacturing method of a mask using the mask blank 10 will next be discussed. The suppression layer 20, which is the feature of the present invention, is the same regardless of the type of mask blank, and the underlayer 14 differs in accordance with the type of mask blank. Thus, a method for manufacturing a mask using the mask blank 10 shown in FIG. 1 will be described below.

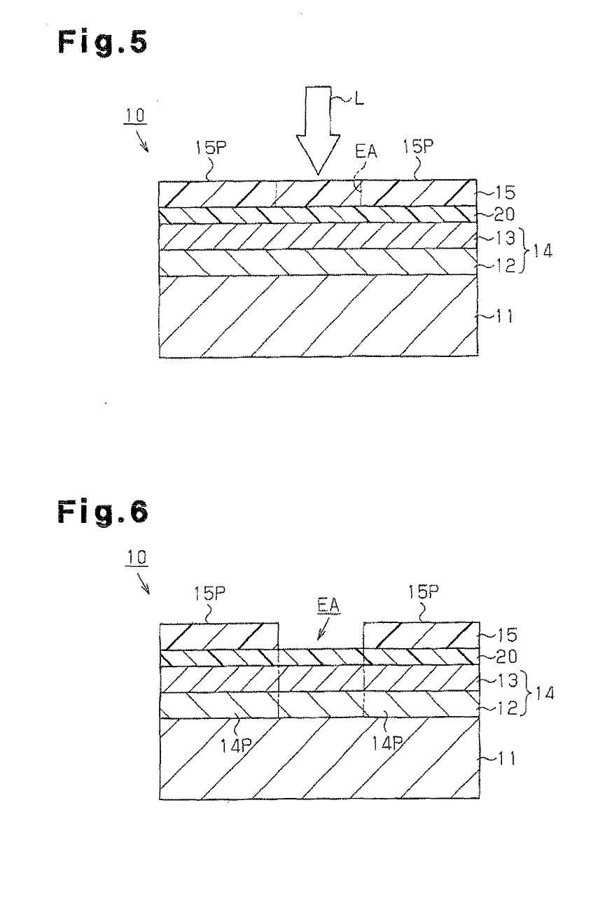

FIG. 4 is a flowchart showing the manufacturing method of the mask, and FIG. 5 and FIG. 6 are step diagrams showing the manufacturing method of the mask. When using the positive type for the mask resist, steps similar to the case of when the negative type is used are performed. A case of using the negative type for the suppression mask resist and the positive type for the mask resist will be described below.

Referring to FIG. 4, an exposure device is first used in the manufacturing method of the mask to irradiate an exposure area EA of the mask layer 15 with exposure light L having a predetermined wavelength, as shown in FIG. 5. A baking device is then used to perform a baking process on the exposed mask layer 15 (exposure step: step S21).

In this state, as shown in FIG. 5, the acid generation agent receiving the exposure light L in the exposure area EA of the mask layer 15 generates acid. The baking process causes the acid generated by the exposure to react with the functional group or functional substance that influences the solubility of the base resin and obtains alkaline solubility in the exposure area EA. The suppression layer 20 immediately below the exposure area EA is irradiated with the exposure light L transmitted through the mask layer 15, and the acid generation agent generates acid. The acid further enhances cross-linkage of the base resin in the suppression layer 20 and further ensures that the suppression layer 20 obtains insolubility. Accordingly, the suppression layer 20 immediately below the exposure area EA mutually diffuses the acid generated by the acid generation agent between the mask layer 15 and the suppression layer 20 and suppresses base diffusion from the underlayer 14.

As a result, the suppression layer 20 causes the mask layer 15 to obtain uniform alkaline solubility over the entire exposure area EA while suppressing reduction of acid in the mask layer 15 at the interface with the mask layer 15. Moreover, the suppression layer 20 maintains the concentration of the acid at the exposure area EA with the mutual diffusion of acid. Thus, the thickness of the suppression layer 20 may be drastically decreased compared to when just relying on just the thickness or density of the suppression layer 20 to suppress the diffusion of acid from the mask layer 15 at the exposure area EA.

After the exposure process is performed on the mask layer 15, the development device is used to supply development liquid over the entire mask layer 15 (development step: step S22).

In this case, as shown in FIG. 6, the development liquid elutes the entire exposure area EA in the mask layer 15, and the region excluding the exposure area EA (hereinafter simply referred to as resist mask 15P) remains on the suppression layer 20. The development liquid does not elute the suppression layer 20 regardless of the elution of the mask layer 15 since the base resin is cross-linked by the excessive baking process and the acid generated by the exposure light L in the suppression layer 20. This suppresses acid reduction in the exposure area EA of the mask layer 15. Thus, the resolution (patterning characteristic) of the mask layer 15 is improved at the interface with the suppression layer 20.

After the development process is performed on the mask layer 15, an etching device is used to perform an etching process over the entire mask blank 10 (etching step: step S23).

In this case, a gas mixture including a halogen group and oxygen is selected as the etching gas to etch the underlayer 14. The region of the suppression layer 20 exposed from the exposure area EA is removed by exposure to the etching gas that includes oxygen. The underlayer 14 immediately below the exposure area EA is removed (etched) by the removal of the region of the suppression layer 20 located immediately above. As a result, the transfer pattern is formed in the region excluding the exposure area EA in the mask blank 10.

This forms the mask layer 15 with high resolution. Thus, the suppression layer 20 is etched with high resolution, and the underlayer 14 is also etched with high resolution. Moreover, the shape of the resist mask 15P during etching is maintained since the thickness of the suppression layer 20 is small. Thus, the underlayer 14 is etched with a higher resolution, and shape defects related to the transfer pattern are suppressed.

### FIRST EXAMPLE

A synthetic silica substrate having a thickness of 0.25 inches and a size of six square inches was used as the transparent substrate 11. Sputtering was performed to form a chromium film on the transparent substrate 11 to obtain the underlayer 14 (underlayer formation step).

Further, spin coating was performed to apply a negative type chemical amplification resist (manufactured by Fuji Film Electronic Materials Co. Ltd.: FEN-270) and form an application film of 10 nm on the chromium film (first application step). Then, an excessive baking process was performed with a hot plate on the application film of the suppression resist under the conditions of 200° C. for fifteen minutes to obtain the suppression layer 20 (first baking step).

An application film of 300 nm was formed on the suppression layer 20 through the spin coating method using the positive type chemical amplification resist (manufactured by Fuji Film Electronic Materials Co. Ltd.: FEP-171) (second application step). Thereafter, the baking process was performed on the application film of the mask resist under the condition of 145° C. for 15 minutes using the hot plate to perform the mask layer 15, thereby obtaining a mask blank 10 of the first example (second baking step).

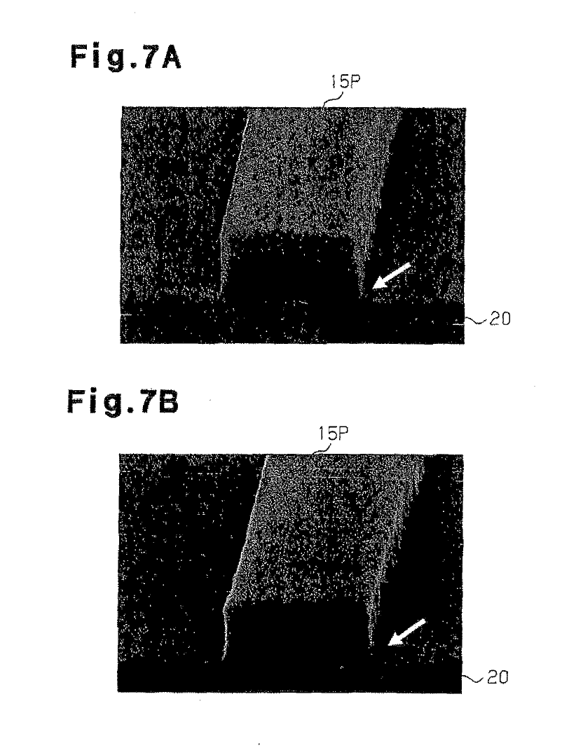

The mask blank 10 of the first example was then exposed with a 50 keV electron beam exposure device, and the baking process was further performed on the exposed mask blank 10 (exposure step). Then, the development process was performed to obtain the resist mask 15P that follows a line/space (L/S) design rule of 100 nm/100 nm and 200 nm/200 nm. FIG. 7A shows an SEM image of the resist mask 15P following the L/S design rule of 100 nm/100 nm.

As shown in FIG. 7A, a so-called “skirt shape” or a shape in which the mask layer 15 spreads out along the suppression layer 20 was not recognized at the bottom portion (portion indicated by the arrow in FIG. 7A) of the resist mask 15P of the first example, and the mask layer 15 was found to have high resolution.

An etching process was performed on the underlayer 14 using the resist mask 15P of the first example to obtain a transfer pattern following the L/S design rule of 100 nm/100 nm and 200 nm/200 nm. An SEM image related to the transfer pattern in which the L/S design rule of 100 nm/100 nm was measured. As a result, variations exceeding 10 nm from the line were not recognized at the bottom portion of the transfer pattern, and the underlayer 14 was found to have high resolution in the same manner as the mask layer 15.

### FIRST COMPARATIVE EXAMPLE

A mask blank 10 of the first comparative example was obtained without performing the first application step and the first baking step but by performing the other steps in the same manner as the first example. The mask blank 10 of the first comparative example was then exposed with the 50 keV electron beam exposure device, and the baking process and the development process were performed on the exposed mask blank 10 to obtain a resist mask 15P of the first comparative example. FIG. 7B shows an SEM image of the resist mask 15P following the L/S design rule of 100 nm/100 nm.

As shown in FIG. 7B, the “skirt shape” in which the mask layer 15 spreads out along the underlayer 14 was recognized at the bottom portion (portion indicated by the arrow in FIG. 7B) of the resist mask 15P of the first comparative example, and the resolution of the mask layer 15 in the first comparative example was found to be greatly inferior to the first example.

The etching process was performed on the underlayer 14 using the resist mask 15P of the first comparative example to obtain a transfer pattern following the L/S design rule of 100 nm/100 nm and 200 nm/200 nm in the same manner as the example. An SEM image related to the transfer pattern in which the L/S design rule is 100 nm/100 nm was measured. As a result, variations of about 30 nm from the line were recognized at the bottom portion of the transfer pattern, and the resolution of the underlayer 14 in the first comparative example was found to be greatly inferior to the first example like the mask layer 15.

### SECOND COMPARATIVE EXAMPLE

In the first application step, an application film of 10 nm was formed from a resist base film formation material (anti-reflection film formation material) (manufactured by Nissan Chemical Industries Ltd.: ARC29A), which does not include an acid generation agent. The other steps were performed in the same manner as the first example to obtain the mask blank 10 of the second comparative example.

The mask blank 10 of the second comparative example was then exposed with the 50 keV electron beam exposure device. Then, the baking process and the development process were performed on the exposed mask blank 10 to obtain the resist mask 15P of the second comparative example. An SEM image of the resist mask 15P of the second comparative example was measured. As a result, the mask layer 15 in the second comparative example was found to be greatly inferior to the first example like the mask layer 15 of the first comparative example.

Subsequently, the etching process was performed on the underlayer 14 with the resist mask 15P of the second comparative example to obtain a transfer pattern in the same manner as the first example. From the measurement result of an SEM image for the transfer pattern of the second comparative example, the resolution of the underlayer 14 in the second comparative example was found to be greatly inferior to the first example like the first comparative example 1.

The mask blank 10 according to the embodiment has advantages described below.

(1) The mask layer 15 is formed using the mask resist and generates acid with the mask resist when receiving the exposure light L. This changes the solubility of the mask layer 15 with respect to the development liquid thereof. The suppression layer 20 is formed using the suppression resist, and generates acid with the suppression resist when subjected to the exposure light L through the mask layer 15. This expresses insolubility of the mask layer 15 with respect to the development liquid thereof.

Accordingly, the thickness of the suppression layer 20, the density of the suppression layer 20, and the acid concentration of the suppression layer 20 suppress changes in the acid concentration of the mask layer 15 in the exposure area EA. Thus, the solubility of the mask layer 15 in the entire exposure area EA is uniform. As a result, the mask blank 10 allows for a thinner suppression layer 20 as compared to when suppressing changes in the acid concentration of the mask layer 15 with the thickness of the suppression layer 20 and the density of the suppression layer 20. Thus, patterning defects of the underlayer 14 are prevented by suppressing changes in the concentration of the acid in the mask blank 10, and the resolution of the underlayer 14 is improved by reducing the thickness of the suppression layer 20.

(2) In addition to use of the chemical amplification resist, which generates acid with the exposure light L, as the “suppression resist”, the suppression layer 20 is formed by performing excessive baking on the suppression resist. Accordingly, the insolubility of the suppression layer 20 is obtained in the manufacturing stage of the mask blank 10.

(3) The film thickness of the suppression layer 20 is 1 nm to 200 nm. Accordingly, improvement in the resolution of the underlayer 14 is ensured since reduction in the thickness of the suppression layer 20 is ensured.

(4) The mask layer 15 and the suppression layer 20 are formed using the chemical amplification resist. This ensures the adhesiveness between the mask layer 15 and the suppression layer 20 and the adhesiveness between the suppression layer 20 and the underlayer 14.

The above-described embodiment may be modified as described below.

The anti-reflection film 13 may be changed to a semi-transmissive film. Further, the underlayer 14 may be, for example, a single layer including only the light-blocking film 12 or the semi-transmissive film. The underlayer 14 is not limited to the stacking order of the light-blocking film 12 and the semi-transmissive film. For example, the light-blocking film 12 may be stacked on the semi-transmissive film.

1. A mask blank comprising:
a transparent substrate;
an etched layer located above the transparent substrate;
a suppression layer located above the etched layer and formed using a first chemical amplification resist; and
a mask layer located above the suppression layer and formed using a second chemical amplification resist;
wherein the mask layer functions to generate acid with the second chemical amplification resist when receiving exposure light and change solubility of the mask layer with respect to a development liquid; and
the suppression layer functions to generate acid with the first chemical amplification resist when receiving the exposure light through the mask layer and obtain insolubility of the mask layer with respect to the development liquid.

2. The mask blank according to claim 1, wherein the suppression layer has a film thickness of 1 nm to 200 nm.

3. The mask blank according to claim 1, wherein the first chemical amplification resist includes:
a solvent that solidifies the first chemical amplification resist;
an acid generation agent that generates acid with the exposure light; and
a mixture of a base resin, which obtains solubility with respect to the development liquid, and a cross-linking agent; and
the suppression layer is generated by removing the solvent and functions to form a cross-linked base resin through reaction of the acid, which is generated by the exposure light, and the cross-linking agent.

4. The mask blank according to claim 1, wherein the suppression layer obtains insolubility when heated by the second chemical amplification resist before receiving the exposure light.

5. The mask blank according to claim 1, wherein the first chemical amplification resist for the suppression layer is a negative type resist.

6. A method for manufacturing a mask blank comprising the steps of:
forming an etched layer on a transparent substrate;
forming a suppression layer on the etched layer using a first chemical amplification resist; and
forming a mask layer on the suppression layer using a second chemical amplification resist;
wherein the step of forming the mask layer includes applying the second chemical amplification resist to the suppression layer and removing solvent from the second chemical amplification resist;
the step of forming the suppression layer includes applying the first chemical amplification resist to the etched layer and heating the first chemical amplification resist to remove solvent from the first chemical amplification resist; and
the suppression layer functions to obtain insolubility of the mask layer with respect to a development liquid due to the first chemical amplification resist when receiving exposure light, which exposes the mask layer.

7. The manufacturing method of the mask blank according to claim 6, wherein the step of forming a suppression layer includes obtaining the insolubility by further heating the first chemical amplification resist after removing the solvent from the first chemical amplification resist.

8. A method for manufacturing a mask, the method comprising the steps of:
manufacturing the mask blank using the method for manufacturing a mask blank according to claim 6;
forming a resist mask by irradiating the mask layer of the mask blank with the exposure light; and
forming a transfer pattern by etching the suppression layer and the etched layer of the mask blank using the resist mask.

9. The mask blank according to claim 2, wherein the first chemical amplification resist for the suppression layer is a negative type resist.

10. The mask blank according to claim 3, wherein the first chemical amplification resist for the suppression layer is a negative type resist.

11. The mask blank according to claim 4, wherein the first chemical amplification resist for the suppression layer is a negative type resist.
